(19) United States
(12) Patent Application Publication
(10) Pub. No.: US 2021/0388914 A1
(43) Pub. Date: Dec. 16, 2021

(54) VALVE DEVICE AND GAS SUPPLY SYSTEM

(71) Applicant: FUJIKIN INCORPORATED, Osaka (JP)

(72) Inventors: Kenji AIKAWA, Osaka (JP); Takahiro MATSUDA, Osaka (JP); Akihiro HARADA, Osaka (JP); Kazunari WATANABE, Osaka (JP); Tomohiro NAKATA, Osaka (JP); Tsutomu SHINOHARA, Osaka (JP)

(73) Assignee: FUJIKIN INCORPORATED, Osaka (JP)

(21) Appl. No.: 17/284,830

(22) PCT Filed: Oct. 21, 2019
(86) PCT No.: PCT/JP2019/041303

§ 371 Date: Apr. 13, 2021

(30) Foreign Application Priority Data
Oct. 26, 2018 (JP) 2018-201829

(51) Int. Cl. F16K 27/00; H01L 21/67

(52) U.S. Cl. CPC F16K 27/003; H01L 21/67017

(57) ABSTRACT

A valve device has a structure more suitable for miniaturization and integration and is used for a semiconductor manufacturing process or the like. A valve device includes: a valve body which is accommodated in an accommodation recess and has a first port and a second port in a bottom surface; and a bonnet nut which has a screw portion formed on an outer periphery thereof and is screwed with the inner periphery of the accommodation recess to press the valve body toward the bottom of the accommodation recess to fix the valve body onto a flow path block. The valve body has first and second annular protrusions for sealing which are formed around the first port and the second port and protrude from a bottom surface. The first and the second annular protrusions are formed so as to share a part thereof.

### TECHNICAL FIELD

The present invention relates to a valve device removably mounted to a flow path block through which a flow path is formed, and a gas supply system using the valve device.

### BACKGROUND ART

In a semiconductor manufacturing process, valves are used to control supply of various process gases to chambers of semiconductor manufacturing apparatuses. In an atomic layer deposition method (ALD method) or the like, high responsiveness and high precision are required for flow rate control of process gases used in a treatment process for depositing a film on a substrate while miniaturizing the valve. To achieve this, the piping should be omitted as much as possible to reduce residual gases in the piping, the valves should be miniaturized, and a large number of valves should be integrated in a location as close as possible to the destination of the process gas.

### PATENT LITERATURE

PTL 1: Japanese Laid-Open Patent Application No. H10-47514

### SUMMARY OF INVENTION

### Technical Problem

Patent Literature 1 discloses an integrated valve that is modularized and screw-coupled directly to a flow path block which is a gas supply destination without using a joint member.

An object of the present invention is to provide a valve device which is more compact and suitable for integration.

### Solution to Problem

The valve device of the present invention is a valve device to be mounted removably to a flow path block through which a flow path is formed,

the valve device comprising: a valve body which is accommodated in an accommodation recess formed in the flow path block and has a first port and a second port in a bottom surface; and

a bonnet nut which has a screw portion formed on an outer periphery thereof and is screwed with the inner periphery of the accommodation recess to press the valve body toward the bottom of the accommodation recess to fix the valve body to the flow path block;

wherein the valve body has first and second annular protrusions for sealing formed around the first and second ports and protruding from the bottom surface; and

the first and second annular protrusions are formed so as to share a part thereof.

Preferably, a configuration may be adopted in which the first and the second annular protrusions as a whole has a generally figure-eight profile.

More preferably, a configuration may be adopted in which the first and the second annular protrusions are formed symmetrically with respect to an imaginary plane including a central axis of the valve body.

The valve device of the present invention may further comprise a bearing provided between the valve body and the bonnet nut to permit the bonnet nut to rotate with respect to the valve body.

Preferably, a configuration may be adopted in which the flow path block has a third port and a fourth port connected to the first port and the second port of the valve body, respectively, via a metal gasket to the bottom surface of the accommodation recess,

the flow path block has third and fourth annular protrusions for sealing formed around the third port and the third port and protruding from the bottom surface of the accommodation recess, and

the third and fourth annular protrusions are formed so as to share a part thereof.

The gas supply system of the present invention is a gas supply system in which a plurality of fluid devices is arranged,

the plurality of fluid devices includes the valve device described above.

Preferably, a configuration may be adopted in which the valve device is provided in the final stage of a supply path of the gas supply system.

### Advantageous Effects of Invention

According to the present invention, since the first and second annular protrusions for sealing the valve body are formed so as to share a part thereof, the distance between the first port and the second ports can be made closer, thereby the outer diameter dimension of the valve body can be reduced. Consequently, a valve device that is more compact and suitable for integration is provided.

### BRIEF DESCRIPTION OF DRAWINGS

FIG. 1 is a perspective view of a valve device according to an embodiment of the present invention, a metal gasket, and a flow path block, including a partial cross section.

FIG. 2 is a longitudinal sectional view of the valve device in FIG. 1 mounted on a flow path block.

FIG. 3 is a bottom view of the valve device in FIG. 1.

FIG. 4 is a top view showing a structure in the accommodating recess of the flow path block.

FIG. 5 is a perspective view of the integrated valve device according to the present embodiment.

FIG. 6 is a schematic diagram showing an example of a gas supply system to which the valve device according to the present embodiment is applied.

### DESCRIPTION OF EMBODIMENTS

Embodiments of the present invention will be described below with reference to the drawings. In the description, the same elements are denoted by the same reference numerals, and repetitive descriptions are omitted as appropriate.

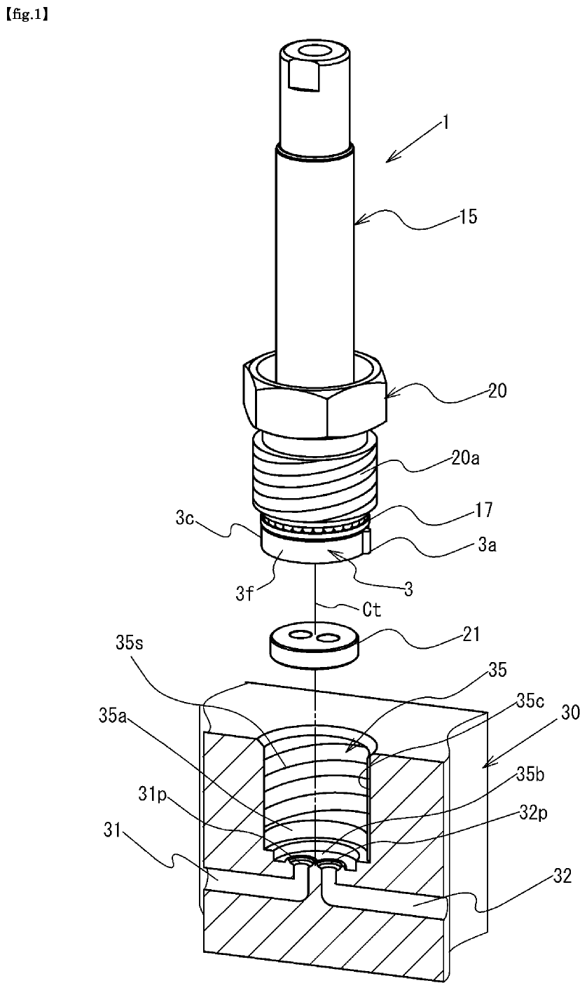

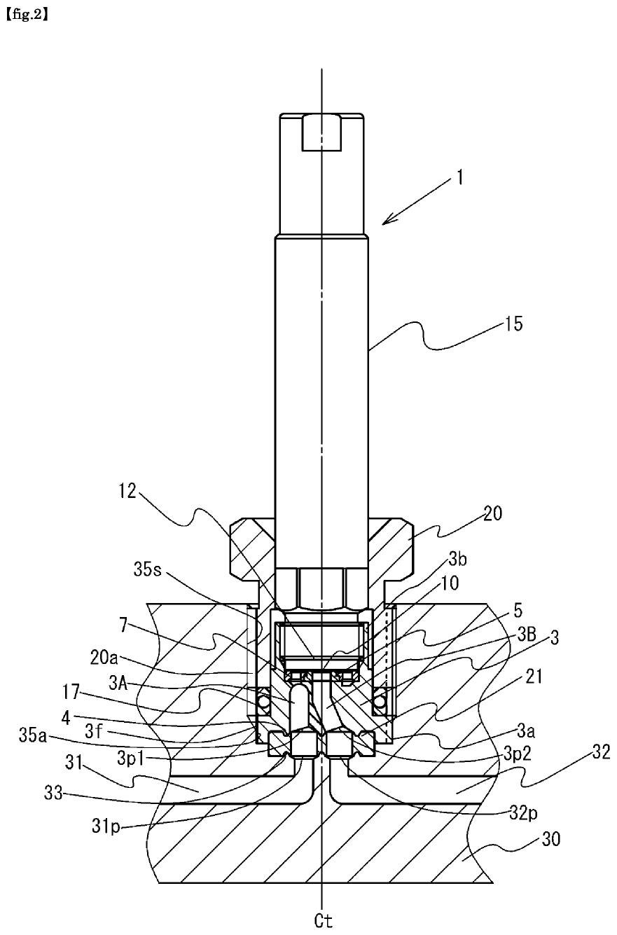

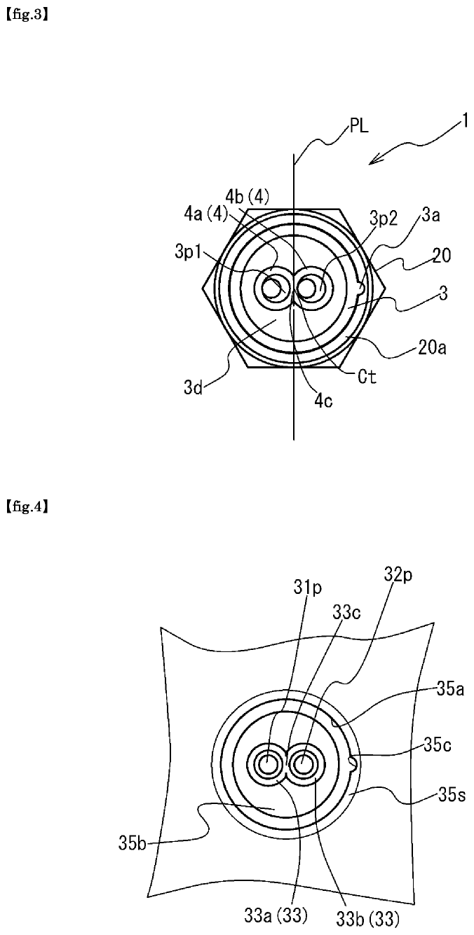

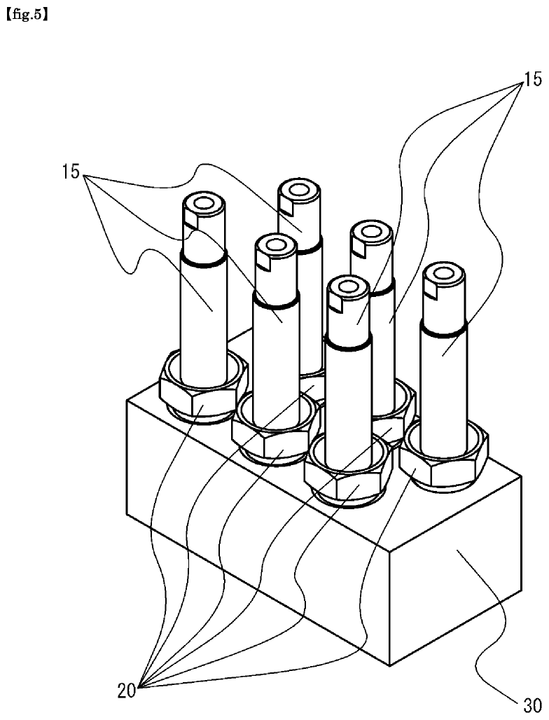

FIG. 1 shows the valve device 1 according to an embodiment of the present invention in a state in which it is detached from a flow path block 30 as a mounting destination. FIG. 2 shows a longitudinal section of the valve device 1 mounted on a flow path block 30. FIG. 3 shows a bottom view of the valve device 1, and FIG. 4 is a top view of the accommodation recess 35 of the flow path block 30.

The valve device 1 has a valve body 3, a valve seat 5, an inner disk 7, a diaphragm 10, an actuator 15, a ball bearing 17 and a bonnet nut 20.

As shown in FIG. 2, the valve body 3 is a rotationally symmetric body about an axis Ct as a central axis and having a cylindrical portion 3b at the top and an enlarged diameter portion 3c at the bottom. In the valve body 3, a flow path 3A and a flow path 3B are formed, one end of the flow path 3A communicates with a port 3p1 which opens at the bottom surface of the valve body 3, and one end of the flow path 3B communicates with a port 3p2 which opens at the bottom surface of the valve body 3.

As shown in the bottom view of FIG. 3, the port 3p1 and the port 3p2 are formed symmetrically with respect to an imaginary plane PL including the axis Ct of the valve body 3. Around the port 3p1 and the port 3p2, a protrusion 4 for sealing protruding from the bottom surface is integrally formed with the valve body 3. The protrusion 4 is provided to be pressed against the gasket 21 to plastically deform the gasket 21.

The protrusion 4 is composed of two annular protrusions 4a and 4b, and the annular protrusion 4a and the annular protrusion 4b are formed so as to share a part thereof. That is, a part of the annular protrusion 4a and a part of the annular protrusion 4b are composed of a common protrusion portion 4c. In the present embodiment, the protrusion 4 has an outer contour shape of a FIG. 8 as a whole, but is not limited thereto. Since a part of the annular protrusion 4a and a part of the annular protrusion 4b are constituted by the common protrusion portion 4c, the distance between the port 3p1 and the port 3p2 can be made closer, and the outer diameter of the valve body 3 can be reduced.

On the valve body 3, as shown in FIG. 2, an annular valve seat 5 is installed around the opening of a flow path 3B at the bottom of the cylindrical portion 3b, and the valve seat 5 is held in place by an inner disk 7. A metallic diaphragm 10 is provided on the inner disk 7 and covers the inner disk 7 completely. The diaphragm 10 contacts with and isolates from the valve seat 5 by a diaphragm presser 12 driven by an actuator 15, thereby communicating and shutting off between the flow path 3A and the flow path 3B. The diaphragm 10 is air-tightly fixed to the valve body 3 by being pressed thereto by a distal end surface of a lower end portion of the actuator 15 screwed into the inner periphery of the cylindrical portion 3b of the valve body 3. The actuator 15 is connected to the valve body 3 by being screwed with the inner periphery of the cylindrical portion 3b of the valve body 3.

As shown in FIG. 1, the enlarged diameter portion 3c formed on the bottom of the valve body 3 supports a ball bearing 17 at its upper end surface, and the outer peripheral surface is an outer peripheral surface portion 3f that fits into an inner peripheral surface portion 35a formed on the inner periphery of the accommodation recess 35 of a flow path block 30 to be described later. On the outer peripheral surface portion 3f, a convex portion 3a is formed for positioning that defines an orientation of the valve body 3 around the axis Ct with respect to the flow path block 30. The convex portion 3a extends in a direction along the axis Ct. The shape of the convex portion 3a is not limited thereto, but when it extends in a direction along the axis Ct, it will move smoothly when engaged with the linear groove portion 35c to be described later.

A bonnet nut 20 formed in a cylindrical shape is disposed around the outer periphery of the valve body 3, and the lower end surface of the bonnet nut 20 is disposed on the enlarged diameter portion 3c of the valve body 3 via the ball bearing 17. On the outer peripheral surface of the bonnet nut 20, an outer screw portion 20a is formed, and screwed with an inner screw portion 35s of the accommodation recess 35 of the flow path block 30 to be described later.

As shown in FIG. 3, in the bottom view of the valve body 3, the convex portion 3a for positioning as described above fits within the outer diameter of the outer screw portion 20a of the outer periphery of the bonnet nut 20.

As shown in FIGS. 1 and 2, the flow path block 30 has a flow path 31 and a flow path 32, and has an accommodation recess 35 having a circular cross-sectional shape. As shown in FIG. 4, a port 31p communicating with the flow path 31 and a port 32p communicating with the flow path 32 open in a bottom surface 35b of the accommodation recess 35. The positions at which the port 31p and the port 32p are formed correspond to the port 3p1 and the port 3p2 of the valve body 3, respectively.

Further, around the port 31p and port 32p, a protrusion 33 for sealing protruding from the bottom surface 35b of the accommodation recess 35 is integrally formed with the flow path block 30. The protrusion 33 is provided to be pressed against the gasket 21 to plastically deform the gasket 21.

The protrusion 33 is composed of two annular protrusions 33a and 33b, and the annular protrusion 33a and the annular protrusion 33b are formed so as to share a part thereof. That is, a part of the annular protrusion 33a and a part of the annular protrusion 33b are constituted by a common protrusion portion 33c. The protrusion 33 is formed at a position corresponding to the protrusion 4 of the valve body 3.

An inner screw portion 35s is formed on the inner periphery of the accommodation recess 35 of the flow path block 30 from the upper end side toward the bottom, and an inner peripheral surface portion 35a into which an outer peripheral surface portion 3f of the valve body 3 is fitted is formed on the bottommost portion. Since the inner diameter of the inner screw portion 35s is formed slightly larger than the inner diameter of the inner peripheral surface portion 35a, the outer peripheral surface portion 3f of the valve body 3 does not interfere with the inner screw portion 35s.

Furthermore, on the inner periphery of the accommodation recess 35, the groove portion 35c extending toward the bottom from the upper end parallel to the axis Ct is formed. The convex portion 3a of the valve body 3 is engaged with the groove portion 35c, and the orientation of the valve body 3 around the axis Ct is defined with respect to the flow path block 30. By engaging the convex portion 3a of the valve body 3 with the groove portion 35c, the ports 3p1 and 3p2 of the valve body 3 are aligned with the ports 31p and 32p of the flow path block 30, respectively. As can be seen from FIG. 2, the groove portion 35c is formed inside the valley diameter of the inner screw portion 35s.

As shown in FIG. 1, the gasket 21 is a disk-shaped member made of metal and has two through holes corresponding to the ports 3p1 and 3p2 of the flow path block 30 and ports 31p and 32p of the valve body 3. Since the gasket 21 is plastically deformable by the protrusion 4 of the valve body and the protrusion 33 of the flow path block 30 described above, the hardness of the gasket 21 is sufficiently lower than that of the protrusion 4 and the protrusion 33. The outer peripheral surface of the gasket 21 is adapted to fit in the recesses formed into the bottom surface 3d of the valve body 3 and the bottom surface 35b of the accommodation recess 35, respectively. A guide ring (not shown) is provided on the outer peripheral surface of the gasket 21, and the structure is such that the gasket 21 does not come off when it is fitted into the recess.

A method of assembling the valve device 1 described above to the flow path block 30 will be described. First, the gasket 21 is held in the recess of the bottom surface 3d of the valve body 3, or is arranged in the recess formed into the bottom surface 3d of the accommodation recess 35. In this state, the outer screw portion 20a of a bonnet nut 20 is screwed into the inner screw portion 35s of the accommodation recess 35 while engaging the convex portion 3a of the valve body 3 with the groove portion 35c of the accommodation recess 35, and the bonnet nut 20 is rotated by using a tool, so that the propulsive force of the bonnet nut 20 is transmitted to the enlarged diameter portion 3c of the valve body 3 via the ball bearing 17. At this time, the ball bearing 17 relieves the rotational force of the bonnet nut 20 so that only the downward propulsive force acts on the valve body 3. Further, even if the force in the rotational direction is applied to the valve body 3, since the convex portion 3a for positioning is engaged with the groove portion 35c of the accommodation recess 35, the relative orientation of the valve body 3 with respect to the flow path block 30 does not deviate.

When the required rotational torque is applied to the bonnet nut 20, the protrusion 4 of the valve body 3 and the protrusion 33 of the flow path block 30 deform the gasket 21, and the flow path 3A and the flow path 31 communicate with air-tightly, and the flow path 3B and the flow path 32 communicate with air-tightly each other.

Since the protrusion 4 and the protrusion 33 are formed symmetrically with respect to the imaginary plane PL, the forces acting on the protrusion 4 and the protrusion 33 are equalized, and the sealing property is stabilized.

As described above, according to the present embodiment, the valve body 3 incorporating the valve seat 5, the diaphragm 10 etc. is housed in the accommodation recess 35 of the flow path block 30, and the orientation mechanism of the valve body 3 with respect to the flow path block 30 is minimized by utilizing screw portion area. Thus, the orientation mechanism in the rotational direction does not hinder the reduction of the outer diameter of the valve body 3.

Further according to the present embodiment, since the protrusion 4 and the protrusion 33 for sealing are configured such that a part of the two annular protrusions is constituted by a common protrusion portion, the distance between the ports can be shortened and the outer diameter of the valve body 3 can be reduced. Consequently, since the inner diameter of the accommodation recess 35 can also be reduced, a valve device suitable for further miniaturization and integration is provided.

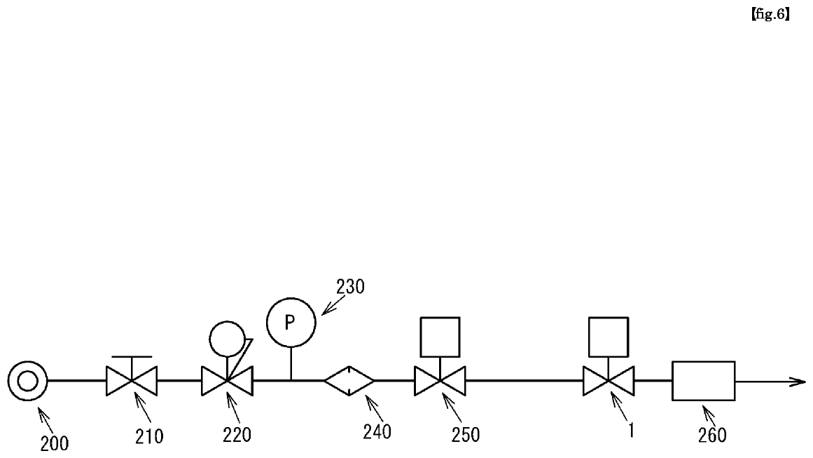

FIG. 5 shows a plurality of integrated valve devices 1.

It can be seen that the valve devices 1 can be brought close to each other within the range in which bonnet nuts 20 can be operated.

FIG. 6 is a schematic diagram showing an example of a gas supply system to which the valve device 1 according to the present embodiment is applied.

The system shown in FIG. 6 is a gas supply system for performing a semiconductor manufacturing process or the like, 200 denotes a gas supply source, 210 denotes a manual valve, 220 denotes a pressure reducing valve, 230 denotes a pressure gauge, 240 denotes a filter, 250 denotes an automatic valve, and 260 denotes a chamber.

In this system, the process gas supplied from the gas supply source 200 is controlled by a plurality of fluid device, such as a manual valve 210, a pressure reducing valve 220, a pressure gauge 230, a filter 240, or an automatic valve 250. The valve device 1 of the present embodiment is provided in the immediate vicinity of the chamber 260, which is a use point (supply destination), that is, the valve device 1 is provided at the final stage of the supply path of the gas supply system, and by performing open-close control of the valve device 1, it is possible to supply the process gas controlled by a plurality of fluid devices to the chamber 260.

The term “fluid device” as used herein refers to a device for controlling flow of fluids, comprising a body defining a fluid flow path and having at least two flow path ports opening at the surfaces of the body. Specifically, including, but not limited to, on-off valves (manual valves, automatic valves), regulators, pressure gauges, filters, and the like.

In the above embodiment, the convex portion 3a and the groove portion 35c are formed at only one location, but the present invention is not limited to this, it can be formed at a plurality of locations.

In the above embodiment, the convex portion 3a is formed in the valve body 3 and the groove portion 35c is formed in the accommodation recess 35 of the flow path block 30, but the convex portion may be formed on the inner peripheral surface portion of the accommodation recess of the flow path block and the groove portion may be formed in the enlarged diameter portion of the valve body.

In the above embodiment, the two annular protrusions constituting each of the protrusions 4 and 33 are circular annular protrusions, but other shapes may be adopted as long as they are annular protrusions.

In the above embodiment, the protrusions 4 and 33 are each formed symmetrically with respect to the imaginary plane PL, but may be each formed asymmetrically as long as they have stable sealing properties.

### REFERENCE SIGNS LIST

1: Valve device
3: Valve body
3A: Flow path
3B: Flow path
3a: Convex portion
3b: Cylindrical portion
3c: Enlarged diameter portion
3d: Bottom surface
3f: Outer peripheral surface
3p1: Port
3p2: Port
4: Protrusion
4a: Annular protrusion
4b: Annular protrusion
5: Valve seat
7: Inner disk
10: Diaphragm
12: Diaphragm presser
15: Actuator
17: Ball bearing
20: Bonnet nut
20a: Outer screw portion
21: Gasket
30: Flow path block
31: Flow path
31p: Port
32: Flow path
32p: Port
33: Protrusion
33a: Annular protrusion
33b: Annular protrusion
35: Accommodation recess
35a: Inner peripheral surface
35b: Bottom surface
35c: Groove portion
35s: Inner screw portion
200: Gas supply source
210: Manual valve
220: Pressure reducing valve
230: Pressure gauge
240: Filter
250: Automatic valve
260: Chamber
Ct: Axis
PL: Imaginary plane

1. A valve device to be mounted removably to a flow path block through which a flow path is formed,
the valve device comprising: a valve body which is accommodated in an accommodation recess formed in the flow path block and has a first port and a second port in a bottom surface; and
a bonnet nut which has a screw portion formed on an outer periphery thereof and is screwed with the inner periphery of the accommodation recess to press the valve body toward the bottom of the accommodation recess to fix the valve body to the flow path block;
wherein the valve body has first and second annular protrusions for sealing formed around the first and second ports protruding from the bottom surface; and
the first and second annular protrusions are formed so as to share a part thereof.

2. The valve device according to claim 1, wherein the first and second annular protrusions as a whole has a generally figure-eight profile.

3. The valve device according to claim 1, wherein the first and second annular protrusions are formed symmetrically with respect to an imaginary plane including the central axis of the valve body.

4. The valve device according to claim 1, further comprising a bearing provided between the valve body and the bonnet nut to permit the bonnet nut to rotate with respect to the valve body.

5. The valve device according to claim 1,
wherein the flow path block has a third port and a fourth port to be connected to the first port and the second port of the valve body, respectively, via a metal gasket to the bottom surface of the accommodation recess,
the flow path block has third and fourth annular protrusions for sealing formed around the third port and the fourth port and protruding from the bottom surface of the accommodation recess, and
the third and fourth annular protrusions are formed so as to share a part thereof.

6. A gas supply system comprising a plurality of fluid devices that are arranged,
the plurality of fluid devices including the valve device as defined in claim 1.

7. The gas supply system according to claim 6, wherein the valve device is provided in the final stage of a supply path of the gas supply system.
